(19) United States
(12) Patent Application Publication
(10) Pub. No.: US 2003/0231478 A1
(43) Pub. Date: Dec. 18, 2003

(54) Circuit board solder side cover

(76) Inventors: Roy Luoma, Fallbrook, CA (US); Robert Shein, El Cajon, CA (US)

Correspondence Address: Ross Patent Law Office, P.O. Box 2138, Del Mar, CA, 92014, US

(21) Appl. No.: 10/171,716

(22) Filed: Jun. 14, 2002

(51) Int. Cl. H05K 7/02; H05K 7/04

(52) U.S. Cl. 361/810

(57) ABSTRACT

A solder side cover comprised of static dissipative flame retardant polypropylene materials and a forming process for making the cover. A press is provided having controlled upper and lower platens configured to clamp, cold form, punch and trim solder side covers with one series of strokes. In preferred embodiments pneumatic actuators are synchronized in a reciprocating slider crank configuration driven by an extensible link to apply a compounded clamp/form/punch action on the material in a progressive manner using a single actuation. A subsequent actuator is employed to perform the precision shearing, maintaining critical edge to hole tolerances. The mechanism is employed to provide adequate force throughout the extent of its rotation while controlling velocity and acceleration in such a fashion as to allow for material deformation without failing the material. Controlled forming forces impart a necessary but predictable stress to generate the impression and avoid warpage and undesirable forming variations. Actuator speeds are controlled by the geometry of the rotating link mechanism so as to provide for tool speed process range optimizations that can accommodate a variety of material modulus and material bend back (material memory) characteristics.

This application relates to printed circuit boards and in particular to covers for the solder sides of such boards.

### BACKGROUND OF THE INVENTION

Printed circuit boards are used extensively in industrial, commercial and consumer products. Typically, these boards are comprised of a board with printed copper connecting strips and several to many individual electronic components such as resistors, capacitors, and integrated circuits mounted on the board after it has been printed. The electrical connections of the electronic components are sometime made by pressing leads into pre-prepared slots, but often the leads are soldered into place. A common practice is to mount or all of the components on one side of the board with the leads extending part way or all the way through to the other side of the board and to apply solder on the other side which is called the solder side. The circuit boards are normally component parts of a larger product and they are typically installed in the larger product by inserting the board into a slot that is prepared for it with multiple electrical contacts which are typically made with male-female pin connections. In many of these applications the slots for the boards are closely spaced to efficiently utilize space in the product. Problems can arise if a solder connection on the solder side contacts another part of the product in the circuit board slot. Also, the board can be damaged on installation or removal of the board if the solder side is scrapped on another part of the product.

For all of the above reasons it is known to provide covers for the solder side of these circuit boards. Logically these covers are called “solder side covers”. They are an important part of the integrated circuit industry. In fact, standards have been developed for these covers because fabricators and users of circuit boards have discovered that the covers themselves can lead to problems. For example, if the material used is too conductive it can cause shorting between the solder connections and many non-conducting materials can develop static buildup in regions of solder connections and this static buildup can interfere with performance. Also, since these circuit boards often generate substantial amounts of heat, the covers must be able to withstand the resulting high temperatures. A typical standard for these covers would be operating temperatures up to 165 F., and static dissipative properties of 1e⁵ to 1e¹¹ ohms/square inch and high volume resistivity as set forth in ASTM D-257, UL 94-VO rated, and oxygen index of less than 30 per ASTM D-2863. Commonly used prior art cover materials are static dissipative polycarbonate materials such as a material sold under the trade name Zelux™. Covers made with these types of materials are typically made in a vacuum forming process in which the material needs to be heat-treated. As a result the process is relatively expensive which results in significant costs for a part that most circuit board fabricators believe should be very inexpensive.

What is needed is a better less expensive, solder side cover.

### SUMMARY OF THE INVENTION

The present invention provides a solder side cover comprised of static dissipative flame retardant polypropylene materials and a forming process for making the cover. A press is provided having controlled upper and lower platens configured to clamp, cold form, punch and trim solder side covers with one series of strokes. In preferred embodiments pneumatic actuators are synchronized in a reciprocating slider crank configuration driven by an extensible link to apply a compounded clamp/form/punch action on the material in a progressive manner using a single actuation. A subsequent actuator is employed to perform the precision shearing, maintaining critical edge to hole tolerances. The mechanism is employed to provide adequate force throughout the extent of its rotation while controlling velocity and acceleration in such a fashion as to allow for material deformation without failing the material. Controlled forming forces impart a necessary but predictable stress to generate the impression and avoid warpage and undesirable forming variations. Actuator speeds are controlled by the geometry of the rotating link mechanism so as to provide for tool speed process range optimizations that can accommodate a variety of material modulus and material bend back (material memory) characteristics.

### BRIEF DESCRIPTION OF THE DRAWINGS

FIG. 1 is an exploded assembly drawing of a printed circuit board with a solder side cover in accordance with the present invention.

FIGS. 2A and 2B are other views of the above assembly.

FIGS. 3A, 3B, and 3C are views of a preferred machine for making solder side covers in accordance with the present invention.

FIGS. 4, 4A, 4B and 4C show views of sections of a preferred solder side cover which are formed in accordance with the present invention.

### DETAILED DECSRIPTION OF PREFERRED EMBODIMENTS

Printed Circuit Board and Solder Side Cover

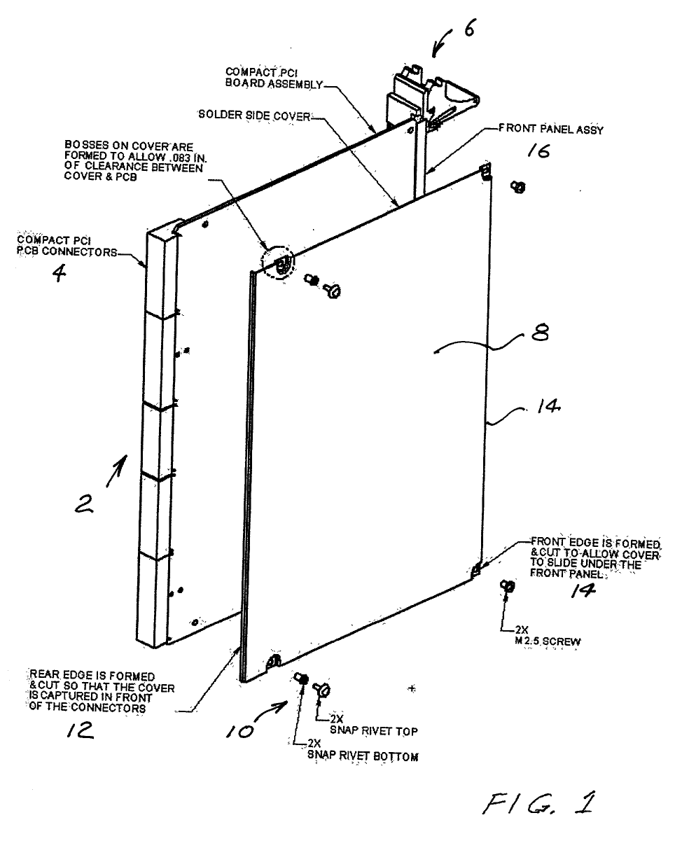

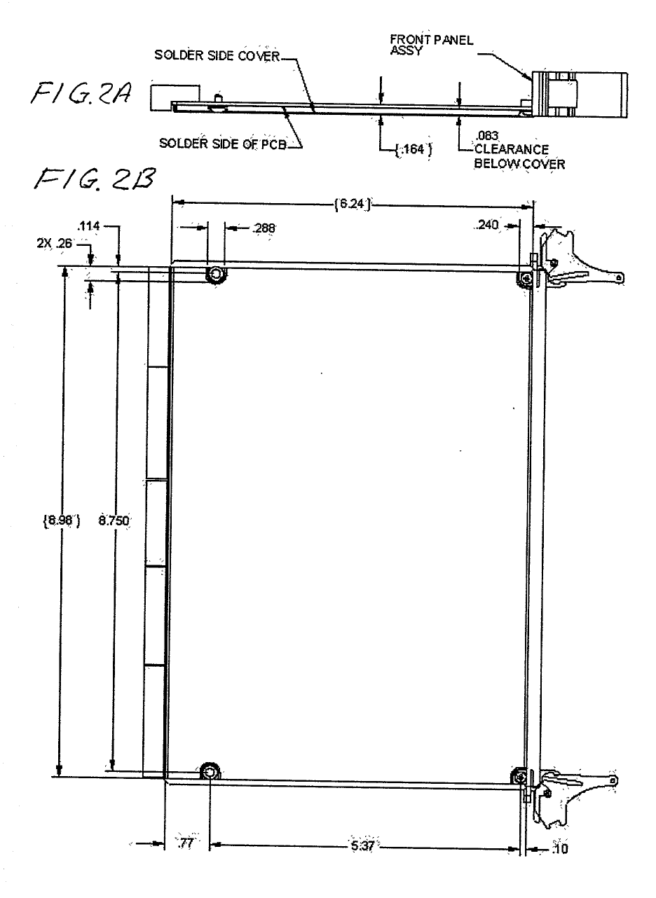

FIG. 1 shows an exploded assembly view of a typical printed circuit board with a solder side cover produced in accordance with the present invention. The printed circuit board 2 is a prior art circuit board utilized in high-speed telephone communication. Shown at the rear edge of the board are a series of CRI PCB connectors 4 for connecting the board into telephone communication equipment. One of two lever arm insertion withdrawal units 6 are provided at both ends of the front of the board. The cover 8 is attached to the board with four screws as shown at 10. The rear edge 12 of the board is formed and cut so that the cover is captured in front of the connectors 4 on the circuit board. The front edge 14 of the board is formed and cut to allow the cover to slide under the front panel 16 of the circuit board. FIGS. 2A and 2B are a side view and a top view of the assembly shown exploded in FIG. 1.

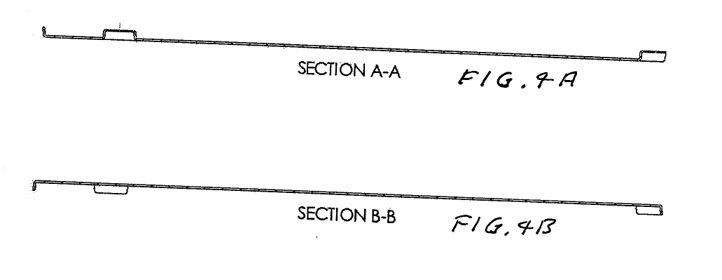

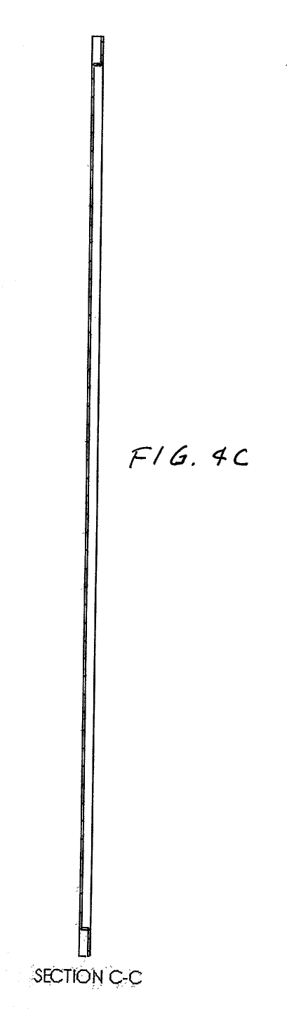

FIG. 4 shows a top view of a preferred embodiment of a solder side cover. FIGS. 4A and 4C show a cross section at one of screw locations as shown on FIG. 4 showing an important indentation at this location which is formed in accordance with the present invention as described below. FIG. 4B shows a cross section view of the rear edge and front edge of the cover.

Cover Material

The preferred material for the solder side cover is static dissipative flame retardant polypropylene sheet. Preferred thicknesses are in the range of about 0.010 to 020. A preferred brand that Applicants have successfully tested is a polycarbonate sheet material, sold by Illinois Tool Works with offices in Glenview, Ill., under the trade name Stantex™. (Other materials on the market which could be used in accordance with this invention are Mirrex7002 made by VPI Mirrex and Pure Therm ESD 1500 made by PurePlast.)

Cover Forming Machine

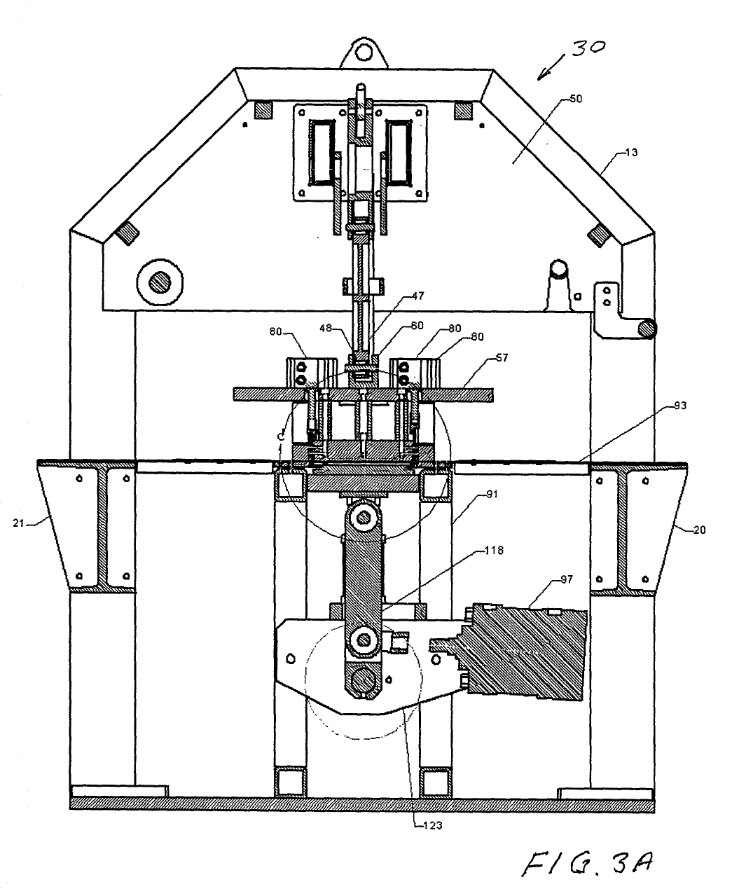

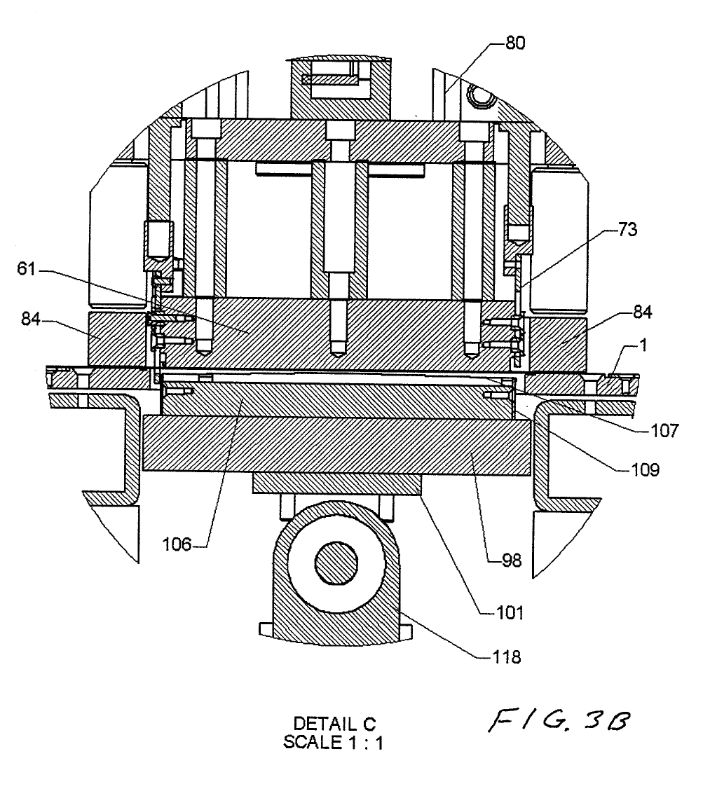

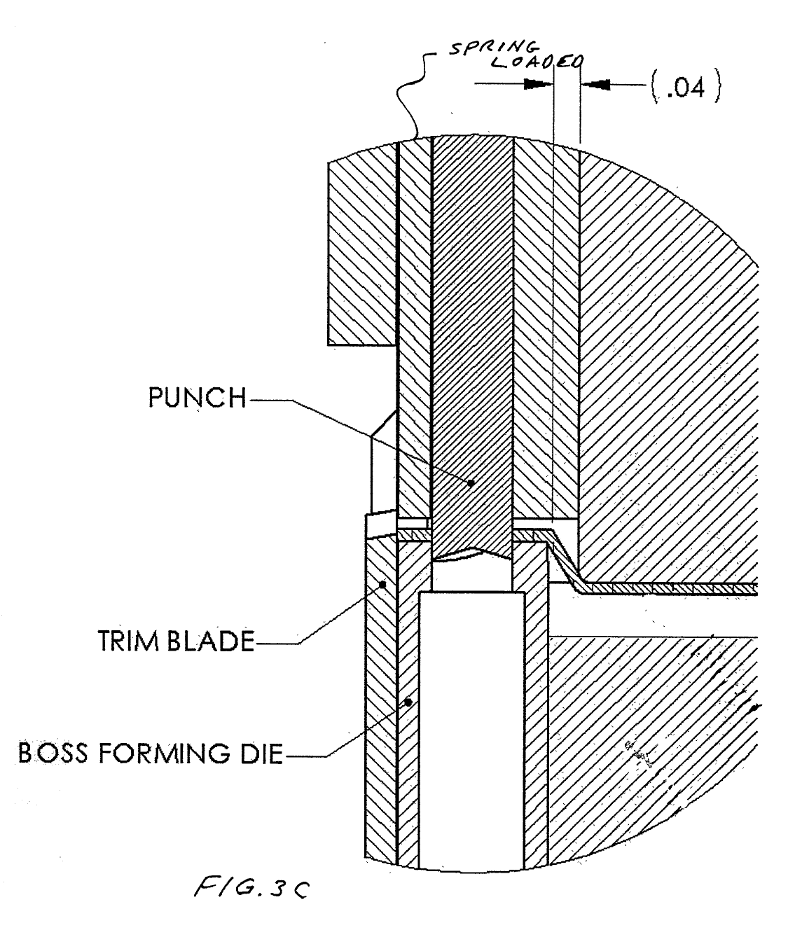

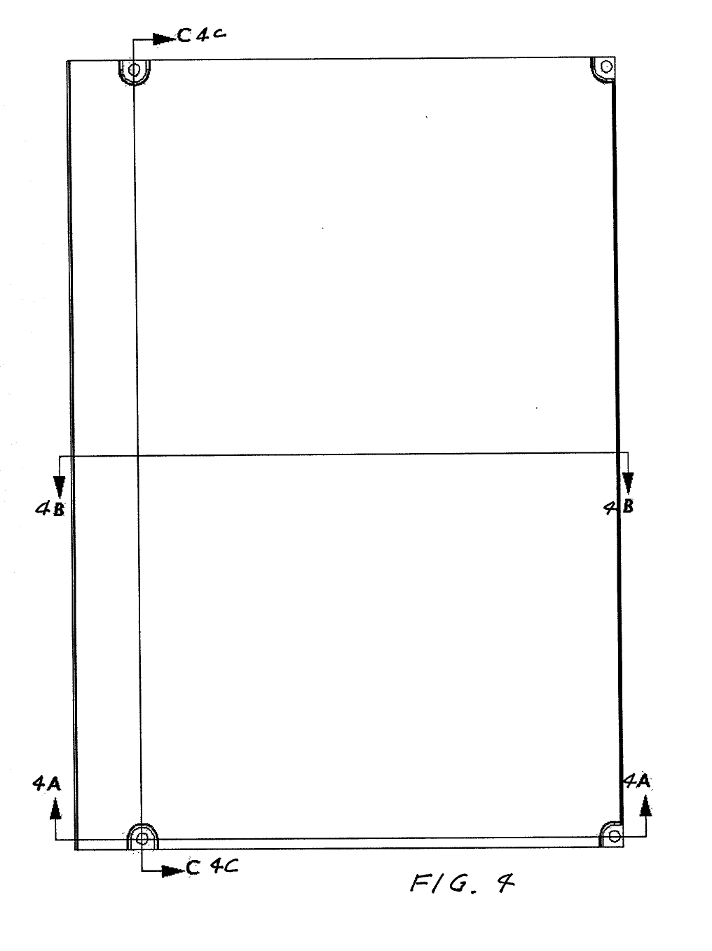

A preferred machine 30 for forming solder side covers in accordance with the present invention is shown in FIGS. 3A, 3B and 3C. FIG. 3B is a blowup of a portion of the machine as shown at 3B in FIG. 3A. FIG. 3C is a further blowup showing a preferred technique for forming the screw holes and the associated indentations. The various parts and functions of the machine will be described and explained in the course of describing the cover forming process in the following section.

Solder Side Cover Forming Process

A preferred process for making solder side covers using the machine 30 shown in FIGS. 3A, B and C is as follows:

Solder Side Cover Forming Station Process

1. The sheet material is placed on material positioning plate 1 between small guides (not shown) on the station top plates 93, which are mounted to the station h-beams 20 & 21 and material positioning plate 1.

2. The upper platen 61 is lowered by an upper pneumatic cylinder (not shown), and the material is clamped using spring loaded clamping bars 84 that move with the upper platen 61. These have a mechanically interlocking feature between bars 84 and plate 1, like a tongue and groove. The material is clamped on all four sides. At the end of the upper platen 61 stroke it is locked in position by the over-centering of the upper module link 47 which is connected to U-shaped clevis pin 48 and the clevis plate 60.

3. The lower platen 98 is raised by the lower pneumatic cylinder 97 which transfers power via the lower module link 118 and the lower module clevis plate 101. As the lower platen 98 moves, the ends are cut, using two triangular shaped blades 107, which are mounted to the lower tool 10 at both ends.

4. The lower platen 98 continues upward and bosses 208 A, B, C and D and step-shaped edges on the front and back edges are formed by the side forming dies 109, and then the holes are punched. The side forming dies 109 are mounted to the lower tool 106. The upper platen 61 carries the female portion of the form tool and the lower platen 98 the male half. The upper platen 61 has the four spring-loaded scalloped punches mounted to it. FIG. 2C is an enlarged view of the section of machine 30 showing the preferred technique for creating the screw holes and their associated indentations in the cover material. Preferably the indentations should be substantially formed before the holes are punched. If the holes are punched first the indentation forming process will deform the holes. To accomplish this in this order, the punches 32 are surrounded by a spring loaded cover that applies pressure to the cover material as the two platens come together so as to hold the cover in position as the indentation is made as shown in FIG. 3C. After the indentations have been substantially formed, the bottom platen continues to rise pushing the cover up. But the punches remain in position as shown in FIG. 3C and as the bottom plate continues to rise the punch punches the screw holes.

5. Then the side cuts are made by two side-cut blades 73 that are actuated by two pneumatic cylinders 80 that are mounted to the upper module platen 57.

6. The formed cover is then removed from the material positioning plate 1.

Proper Pressure and Timing is Important

In their testing and experiments Applicants have learned that proper pressure with proper timing is very important. Pressure must be applied slowly enough to permit the material to deform gradually. Otherwise it will tear. Applicants test have shown that a preferred technique is to apply about 8500 pound force to form the cover described above. The force preferably is provided with the platens moving at the rate of about ¼ inch per second. The 8500 pounds are applied and preferably held for at least 4 seconds. The area of the platen is about 6×9 or 54 square inches which indicates a pressure of about 150 psi. Pneumatic actuators are synchronized in a reciprocating slider crank configuration driven by an extensible link to apply a compounded clamp/form/punch action on the material in a progressive manner using a single actuation. As described above, an actuator is subsequently employed to perform the precision shearing, maintaining critical edge to hole tolerances. The mechanism is employed to provide adequate force throughout the extent of its rotation while controlling velocity and acceleration in such a fashion as to allow for material deformation without failing the material. Controlled forming forces impart a necessary but predictable stress to generate the impression and avoid warpage and undesirable forming variations. Actuator speeds are controlled by the geometry of the rotating link mechanism so as to provide for tool speed process range optimizations that can accommodate a variety of material modulus and material bend back (material memory) characteristics.

While the above description contains many specifications, the reader should not construe these examples as a limitation on the scope of the invention, but merely as exemplifications of preferred embodiments thereof. For example, solder side covers may be used in various standard and custom electronic formats as well as in varying sizes of standard and custom printed circuit boards. Electronic format examples are compact PCI, VME, VME64, etc. Standard printed circuit board sizes vary; examples are: 3U, 6U, and 9U and other sizes. Accordingly the reader is requested to determine the scope of the invention by the appended claims and their legal equivalents, and not by the examples given above.

We claim:

1. A solder side cover comprised of:
A) a static dissipative flame retardant polypropylene material, said material being cold formed to provide a cover for integrated circuit boards,
B) an attachment means for attaching said board to the solder side of an integrated circuit board.

2. A solder side cover as in claim 1 wherein said attachment means is screws.

3. A solder side cover as in claim 1 wherein said integrated circuit board in needed for a telephone system.

4. A method of making solder side covers comprising the steps of:
A) providing a cold press configured to perform clamping, cutting, forming and punching of said solder side cover,
B) placing a sheet of static dissipative flame retardant polypropylene material on said cold press, and clamp, form, and punch said material,
C) activate an actuator to perform precision shearing while maintaining critical edge to hole tolerances.

5. A method as in claim 1 wherein said polypropylene material is Stantex™.

6. A method as in claim 1 wherein said polypropylene material is chosen from a group of materials consisting of:
Mirrex 7002 and Pure Therm 1500.

7. A method as in claim 1 wherein said forming step comprised applying a force of at least 8,000 pounds and holding that force for at least 4 seconds.
